(19) United States
(12) Patent Application Publication
(10) Pub. No.: US 2001/0035361 A1
(43) Pub. Date: Nov. 1, 2001

(54) Container for an optical article

(75) Inventors: Hitoshi Mishiro, Ibaraki (JP); Shinya Kikugawa, Kanagawa (JP); Yoshiaki Ikuta, Kanagawa (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Asahi Glass Company, Limited, Tokyo (JP)

(21) Appl. No.: 09/795,480

(22) Filed: Mar. 1, 2001

(30) Foreign Application Priority Data
Apr. 26, 2000 (JP) 2000-125996

(51) Int. Cl. B65D 85/38; B65D 85/48; G03F 9/00; G02B 27/46

(52) U.S. Cl. 206/316.1; 206/454; 430/5; 359/562

(57) ABSTRACT

A container for accommodating an optical article made of synthetic quartz glass includes synthetic resin as a base material, and a coating film provided on a substantially entire area of at least an inner surface thereof, the coating film being substantially impermeable to a gas evolved from the synthetic resin as the basic material of the container.

The present invention relates to a container for an optical article, which can be used for transportation, conveyance or storage of various optical articles made of synthetic quartz glass, such as a lens, a window, an etalon, a photomask, a pellicle membrane and a pellicle frame.

In the exposure process for fabrication of semiconductor devices, light having a short wavelength has been employed to meet the need for microfabrication in design rules. In later years, a technique to employ light having a wavelength band not longer than a wavelength of 220 nm as a light source has been proposed and used. As the optical material that can be used in such a wavelength band, some synthetic quartz glass (e.g., one manufactured by Asahi Glass Company, Limited and sold under the name of QF), a fluor, a fluoroplastic polymer film and so on have been known. The synthetic quartz glass is glass substantially made of only silica, which is obtained by, e.g., reacting a source of silica and a source of oxygen in a vapor phase to grow a porous member made of silica and called soot, followed by sintering.

Since optical articles made of these optical materials are sensitive to external impact, scratch easily and are adversely affected by dust caused by the vibration during transportation or storage, there have been used containers for an optical article, which are molded of relatively elastic synthetic resin in comparison with metal, such as polyacrylate, polystyrene, polypropylene, polyethylene, polycarbonate and ABS resin. These materials can be produced in great quantities at commercially low cost by injection molding, press molding or extrusion molding. However, it has been known that in a case wherein an optical article for a wavelength band not longer than a wavelength of 220 nm is used, even if the optical article has been sufficiently cleaned, the light transmittance of the optical article has lowered, and recleaning is required before use in some cases. Recleaning requires a great load in terms of cost. It is an object of the present invention to solve this problem.

The inventors have been found that the reason why an optical article has light transmission lowered, though having sufficient light transmittance as a material property is that an organic gas (a gas originating from a plasticizer, an unreacted monomer and so on) evolved from a container for the optical article adheres on the optical article in the container, and the light transmittance lowers by about 3-5% when the optical article is taken out of the container.

When this phenomenon is applied to a photomask substrate, the phenomenon that the light transmittance is lowered by a gas evolved from the container takes place in respect processes, e.g., \mathring{1} transportation, conveyance or storage until forming a film, such as a chromium film, after polishing and cleaning a substrate, \mathring{2} transportation, conveyance or storage until patterning the substrate with the film formed thereon, \mathring{3} transportation, conveyance or storage until using the patterned substrate in a stepper for exposure, and \mathring{4} storage for next use of the substrate used for exposure. The phenomenon creates a problem that the degree of exposure varies from part to part to prevent equal exposure.

Although there is a proposal that the amount of the evolving gas is decreased by subjecting the container to heat treatment or vacuum heat treatment before using the container for an optical article, it is not possible to obtain a sufficient effect for the synthetic resin listed above.

To solve the problems, the present invention provides a container for accommodating an optical article made of synthetic quartz glass, comprising synthetic resin as a base material, and a coating film provided on a substantially entire area of at least an inner surface thereof, the coating film being substantially impermeable to a gas evolved from the synthetic resin as the basic material of the container. The present invention also provides a container for accommodating an optical article made of synthetic quartz glass, comprising synthetic resin as a base material, wherein an optical article accommodated in the container can have a difference between light transmission just after accommodation and light transmission in 100 hours after accommodation restrained by 1% or less with respect to a wavelength of 157.6 nm.

It is preferable that the coating film, which is an inorganic coating film or, in particular, a coating film made of metal, oxide thereof or acid nitride, is formed the entire are of the at least inner surface at a thickness of not less than 100 nm, and that a coupling agent is interposed between the area with the coating film formed thereon and the coating film.

In the drawings:

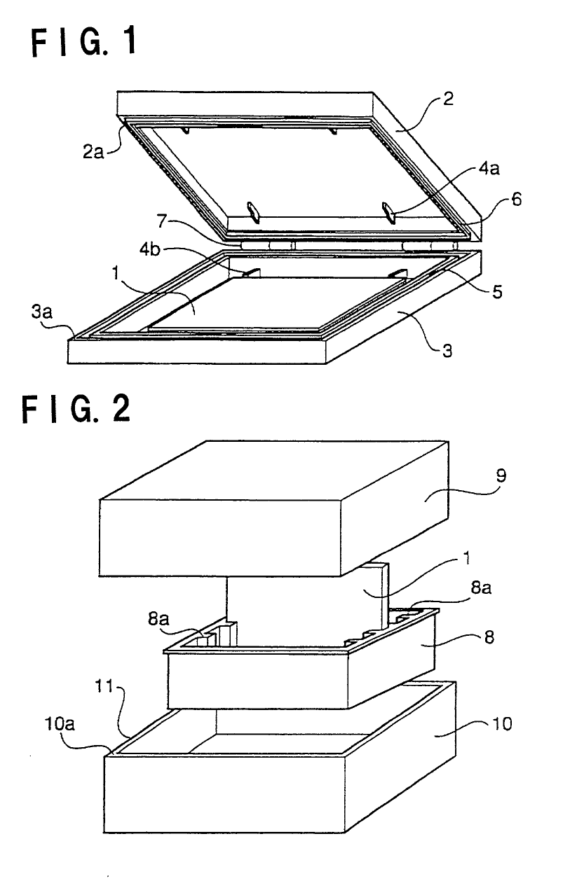

FIG. 1 is a perspective view showing a container for an optical article, having a single structure;

FIG. 2 is a perspective view showing a container for an optical article, having a multiple structure; and

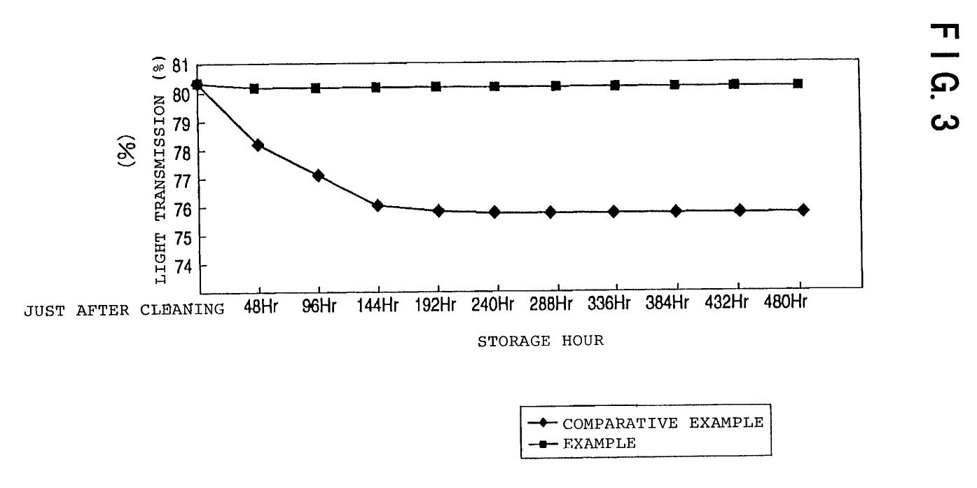

FIG. 3 is a graph showing changes in light transmission with time with respect to a synthetic quartz substrate prepared according to an example and a comparative example (a wavelength of 157.6 nm).

Now, the present invention will be described in detail, referring to the accompanying drawings.

The shape or the structure of the container according to present invention has no limitations as long as it can accommodate an optical article. However, the container preferably has such a shape or structure to accommodate an optical article in gas-tight fashion in terms of dust control. The container may have a structure to accommodate a single optical article or a structure to accommodate plural optical articles, matching the number of optical articles to be accommodated.

For example, a container for an optical article, which has a single structure, and which closes an upper half 2 and a lower half 3 to accommodate an optical article 1, is shown as an example in FIG. 1. The upper half 2 and the lower half 3 have, respectively, hold-downs 4a, 4b provided thereon so as to project from an inner wall, restricting the movement of the optical article 1 during accommodation. The upper half 2 has a mating surface 2a provided with a ridge 6 over the entire periphery thereof, and the lower half 3 has a mating surface 3a provided with a recess 5 over the entire periphery thereof. When the upper half 2 and the lower half 3 are closed, a gas-tight structure is provided. The upper half 2 and the lower half 3 are connected by hinges 7 so as to be opened and closed.

In FIG. 2 is shown a container for an optical article, which has a multiple structure, and which accommodates an optical article 1 in an inner container 8 and encloses the inner container 8 in an outer upper half 9 and an outer lower half 10 to accommodate the optical article 1. The inner container 8 has an inner wall provided with plural projections 8a to sandwich and hold the optical article 1 between adjoining projections. The outer upper half 9 has a mating surface (not shown) provided with a ridge (not shown) over the entire periphery thereof, and the outer lower half 10 has a mating surface 10a provided with a recess 11 over the entire periphery thereof. When the outer upper half 9 and the outer lower half 10 are closed, a gas-tight structure is provided.

Both containers may be molded out of synthetic resin, such as polyacrylate, polystyrene, polypropylene, polyethylene, polycarbonate and ABS resin, as in the conventional containers in order that the containers can provide not only strength required and sufficient to protect the accommodated optical article 1 against external impact or vibration but also elasticity to prevent a surface or a supported site of the optical article 1 from scratching.

In the containers according to the present invention, a coating film, which is substantially impermeable to a gas evolved from the synthetic resin as the basic material of the containers, is formed on the substantially entire area of at least an inner surface of the containers in consideration of the problem with gas generation. By this arrangement, the optical article accommodated in each of the containers can have the difference between light transmission just after accommodation and light transmission in 100 hours after accommodation restrained by 1% or less with respect to a wavelength of 157.6 nm. In terms of gas-impermeability, it is preferable that the coating film is an inorganic coating film, in particular a coating film made of metal, oxide thereof or acid nitride, and that the coating film has a thickness of not less than 100 nm. The coating film is formed on at least the inner surface of each of the containers. For example, in the case of the container shown in FIG. 1, the coating film is formed on the inner surface (including the hold-downs 4a) and the mating surface 2a (including the ridge 6) of the upper half 2, and on the inner surface (including the hold-downs 4b) and the mating surface 3a (including the recess 5) of the lower half 3. On the other hand, in the case of the container shown in FIG. 2, the coating film is formed on the entire surface of the inner container 8, on the inner surface and the mating surface (including the ridge) of the outer upper half 9, and on the inner surface and the mating surface 10a (including the recess 11) of the outer lower half 10. The coating film may be formed on the entire surface of each of the containers.

As the coating film material, a chromium film made of chromium metal (Cr) , chromium oxide (CrOₓ), chromium oxynitride (CrOₓN_{y}) and so on, and oxide of chromium or acid nitride are preferable since these materials are superior in corrosion resistance in addition to a gas-barrier property. Other metal, metal alloy, and oxide or acid nitride thereof are acceptable. Even if the coating film is made of Si or SiO₂, the coating film can ensure a sufficient gas-barrier property. In some applications of the optical article, an ITO material may be employed to ensure the transparency of the container. It is preferable that the thickness of the coating film is not less than 100 nm. If the coating film is thinner, the coating film could be peeled off by mechanical cleaning, such as abrasive cleaning using a brush, or by ultrasonic cleaning in a cleaning process after formation of the coating film, creating a problem in durability. It is preferable that the thickness of the coating film is not less than 200 nm.

In order to form the coating film, known technology, such as sputtering, vapor deposition, ion plating, and a CVD method, may be properly selected according to the kind of the synthetic resin or the kind of the coating film material. In order to enhance the adhesion of the coating film, the coating film may be formed by any one of such known technology after a coupling agent, such as a silane coupling agent, has been applied on a coating film forming surface (a surface of the synthetic resin). Or, the coating film may have such a multilayer structure that a coating film, which is made of a metal stated earlier, oxide thereof or acid nitride, is formed after a film having a superior adhesive property with the coating film forming surface has been formed on the coating film forming surface.

In the containers according to the present invention thus constructed, the coating film can prevent a gas from entering into the containers from the synthetic resin as the basic material and staying there. The optical article accommodated in each of the containers can have a difference between light transmission just after accommodation and light transmission in 100 hours after accommodation restrained by a decrease of 1% or less with respect to a wavelength of 157.6 nm as shown in the example stated below.

Now, an Example and a Comparative Example will be shown to describe the present invention in more detail, though the present invention is not limited to the Example.

### EXAMPLE and COMPARATIVE EXAMPLE

A synthetic quartz ingot, which was produced by a known technique, was cut into pieces having a size of 153.0 mm×153.0 mm×6.55 mm (thickness) by a slicer having a cutter on an inner periphery thereof, and the cut pieces were subjected to chamfering, lapping and polishing. After that, the pieces were dipped for 2 minutes in a bath, which contained a solution of 95 wt % sulfur acid:30 wt % hydrogen peroxide=50:50 (volume ratio). After the dipped pieces were rinsed with pure water, the pieces were dried in a moist air bath of isopropyl alcohol, obtaining plural synthetic quartz substrates for a photomask having a size of 152.0 mm×152.0 mm×6.45 mm (thickness). When the light transmission of these substrates with respect to a wavelength of 157.6 nm was measured by a vacuum ultraviolet spectrophotometer (UV-201M made by Bunko-Keiki Co., Ltd.), it was shown that the light transmission with respect to that wavelength was 80.3% on average.

On the other hand, two kinds of containers for an optical article, i.e., a container for an optical article A (Comparative Example) which had the structure shown in FIG. 2, and which included an inner container 8 made of polypropylene, and an outer upper half 9 and an outer lower half 10 made of ABS resin, and a container for an optical article B (Example), wherein the inner surface of the inner container 8, the inner surface and the mating surface of the outer upper half 8, and the inner surface and the mating surface 10a of the outer lower half 10 of the container constructed in the same manner as the container A had Cr formed thereon in a thickness of 200 nm by sputtering, were prepared. The respective containers A and B were subjected to abrasive cleaning, using a synthetic detergent and a brush. After the containers thus cleaned were ultrasonically rinsed in ultrapure water, the containers thus rinsed were left for dry in a clean room for 24 hours.

The synthetic quartz substrates were accommodated in the respective containers A and B. The synthetic quartz substrates were taken out every 48 hours, and the light transmission of the synthetic quartz substrates with respect to a wavelength of 157.6 nm was measured by the vacuum ultraviolet spectrophotometer as in the measurement stated earlier. As shown in FIG. 3, the results of the measurements showed that the light transmission did not lower even in 480 hours in the case of the synthetic quartz substrates accommodated in the container B, while the light transmission lowered to 76.0% in 144 hours in the case of the synthetic quartz substrates accommodated in the container A.

As explained, the containers according to the present invention can almost completely avoid the generation of a gas from the synthetic resin as the basic material and restrain a decrease in the light transmission of various optical articles made of, in particular, synthetic quartz glass during transportation, conveyance and storage. When a film, such as an anti-reflection coating, is applied to an optical article, such as a lens, to improve the light transmission of a used wavelength, insufficient cleaning before formation of the film could create a problem in that the gas stated earlier stays under the film to lower the light transmission. The containers according to the present invention can be hardly susceptible to the problem.

Since there is no limitation in the material of the synthetic resin as the basic material, most of containers for an optical article presently available can enjoy the effects of the present invention by only being subjected to the coating film formation treatment, which means that the present invention has a great deal of versatility. In addition, the present invention can eliminate the heat treatment for every use, which is advantageous in terms of maintenance.

The entire disclosure of Japanese Patent Application JP2000-125996 filed on Apr. 26, 2000 including specification, claims, drawings and summary are incorporated herein by reference in its entirety.

What is claimed is:

1. A container for accommodating an optical article made of synthetic quartz glass, comprising synthetic resin as a base material, and a coating film provided on a substantially entire area of at least an inner surface thereof, the coating film being substantially impermeable to a gas evolved from the synthetic resin as the basic material of the container.

2. The container according to claim 1, wherein the coating film is an inorganic coating film.

3. The container according to claim 1, wherein the coating film is a coating film made of metal, oxide thereof, or acid nitride.

4. The container according to claim 3, wherein the metal is chromium.

5. The container according to claim 1, wherein the coating film has a thickness of not less than 100 nm.

6. The container according to claim 1, wherein a coupling agent is interposed between the area with the coating film formed thereon and the coating film.

7. The container according to claim 1, wherein the synthetic resin as the base material is at least one material selected from the group of polyacrylate, polystyrene, polypropylene, polyethylene, polycarbonate and ABS resin.

8. The container according to claim 1, further having a gas-tight structure.

9. The container according to claim 1, wherein an optical article accommodated in the container can have a difference between light transmission just after accommodation and light transmission in 100 hours after accommodation restrained by 1% or less with respect to a wavelength of 157.6 nm.

10. A container for accommodating an optical article made of synthetic quartz glass, comprising synthetic resin as a base material, wherein an optical article accommodated in the container can have a difference between light transmission just after accommodation and light transmission in 100 hours after accommodation restrained by 1% or less with respect to a wavelength of 157.6 nm.
